(19) United States
(12) Patent Application Publication
(10) Pub. No.: US 2026/0371837 A1
(43) Pub. Date: Nov. 19, 2026

(54) COMPOSITE MATERIAL, LIGHT-EMITTING DEVICE INCLUDING SAME, AND PREPARATION METHOD THEREFOR

(71) Applicant: TCL Technology Group Corporation, Huizhou, Guangdong (CN)

(72) Inventor: Kunfei TIAN, Huizhou, Guangdong (CN)

(73) Assignee: TCL Technology Group Corporation, Huizhou, Guangdong (CN)

(21) Appl. No.: 19/130,944

(22) PCT Filed: Oct. 31, 2023
(86) PCT No.: PCT/CN2023/128304

§ 371 Date: May 16, 2025

(30) Foreign Application Priority Data
Nov. 18, 2022 (CN) 202211447264.2

(51) Int. Cl. H10K 50/15; H10K 50/17; H10K 50/828; H10K 71/15; H10K 85/10; H10K 102/10

(52) U.S. Cl. CPC H10K 50/15; H10K 50/171; H10K 50/828; H10K 71/15; H10K 85/1135; H10K 85/115; H10K 2102/102; H10K 2102/103

(57) ABSTRACT

A composite material, a light-emitting device including same and a preparation method therefor are provided, and relates to the field of photoelectricity. The composite material includes a hole transport material and a voltage stabilizer, where the voltage stabilizer includes a substituted aromatic ketone, and at least one substituent of the aromatic ketone is an electron-donating group. The composite material has high electron affinity and high charge transport efficiency.

This disclosure claims priority of the Chinese patent application with the Chinese Patent Application No. 202211447264.2, filed in the China National Intellectual Property Administration on Nov. 18, 2022, and entitled “COMPOSITE MATERIAL, LIGHT-EMITTING DEVICE INCLUDING SAME, PREPARATION METHOD THEREFOR, AND DISPLAY DEVICE”, which is incorporated herein by reference in its entirety.

### TECHNICAL FIELD

The present disclosure relates to a field of photoelectricity, and in particular to a composite material, a light-emitting device including same, and a preparation method for the light-emitting device.

### BACKGROUND

The light-emitting device mainly relies on the interaction of the opposite movement of the electron-hole pairs to work, and therefore the transmission balance of the electron-hole pairs is very important for the light-emitting device. If the material of the hole transport layer may not ensure sufficient hole injection, a large number of electrons in the device will gather and leak to the hole transport layer, and the excessive electron gathering causes uneven distribution of the electric field of the device, thereby causes irreversible damage to the hole transport layer, causes the device to be unstable or invalid, and the efficiency and the lifetime of the device are also reduced.

The prior art usually realizes the transmission balance of the electron-hole pairs of the light-emitting device by limiting the electron injection, so as to avoid the damage of the excessive electrons to the hole transport layer, but the limitation of the electron injection may cause the reduction of the device efficiency.

### Technical Solution

At least one embodiment of the present disclosure provides a composite material including a hole transport material and a voltage stabilizer;
where the voltage stabilizer includes a substituted aromatic ketone, and at least one substituent of the aromatic ketone is an electron-donating group.

Optionally, the electron-donating group includes one or more of a hydroxyl, an alkoxy, a phenoxy, a benzyloxy, and an acyloxy.

Optionally, the voltage stabilizer includes a substituted aromatic ketone having 2 to 5 benzene ring structures, and the aromatic ketone having 2 to 5 benzene ring structures includes one or more of 4-allyloxy-2-hydroxybenzophenone, 2-hydroxy-4-(methacryloyloxy)benzophenone, 4′-phenoxyacetophenone, 4′-benzyloxy-2′-hydroxyacetophenone, 5,5′-methylenebis(2-hydroxy-4-methoxybenzophenone), and 4-hydroxy-4′-phenoxybenzophenone.

Optionally, a mass ratio of the voltage stabilizer to the hole transport material is 1:(2-20).

Optionally, the hole transport material includes at least one of TFB, CuPc, PVK, Poly-TPD, DNTPD, TCATA, TCCA, CBP, TPD, NPB, NPD, PEDOT:PSS, TAPC, MCC, F4-TCNQ, HATCN, 4,4′,4′-tris(N-3-methylphenyl-N-phenylamino) triphenylamine, polyaniline, a transition metal oxide, a transition metal sulfide, a transition metal stannide, doped graphene, undoped graphene, and C60.

Correspondingly, the present disclosure provides a light-emitting device including a cathode, an anode, a light-emitting layer, and a hole transport layer. A material of the hole transport layer includes the composite material above.

Optionally, a material of the anode and a material of the cathode respectively independently include one or more of a metal, a carbon material, and a metal oxide; the metal includes one or more of Al, Ag, Cu, Mo, Au, Ba, Ca, Yb, and Mg; the carbon material includes one or more of graphite, carbon nanotube, graphene, and carbon fiber; the metal oxide includes a doped or undoped metal oxide, which includes one or more of ITO, FTO, ATO, AZO, GZO, IZO, MZO, and AMO; the anode and the cathode may further include a composite electrode with metal sandwiched between doped or undoped transparent metal oxides; the composite electrode includes one or more of AZO/Ag/AZO, AZO/Al/AZO, ITO/Ag/ITO, ITO/A/ITO, ZnO/Ag/ZnO, ZnO/Al/ZnO, ZnS/Ag/ZnS, ZnS/Al/ZnS, TiO₂/Ag/TiO₂, and TiO₂/Al/TiO₂; and/or
a material of the light-emitting layer includes one or more of an organic light-emitting material and a quantum dot light-emitting material; the organic light-emitting material includes at least one of 4,4′-bis(N-carbazole)-1,1′-biphenyl:tris[2-(p-tolyl)pyridine-C2,N) iridium(III), 4,4′,4″-tris(carbazole-9-yl)triphenylamine:tris[2-(p-tolyl)pyridine-C2,N) iridium, a diaromatic anthracene derivative, a stilbene aromatic derivative, a pyrene derivative, a fluorene derivative, TBPe fluorescent material, TTPX fluorescent material, TBRb fluorescent material, and DBP fluorescent material; the quantum dot light-emitting material includes at least one of a single-structure quantum dot, a core-shell structure quantum dot, and a perovskite semiconductor material; a material of the single-structure quantum dot, a core material of the core-shell structure quantum dot and a shell material of the core-shell structure quantum dot respectively include at least one of an II-VI compound, an IV-VI compound, an III-V compound, and an I-III-VI compound; the II-VI compound includes at least one of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the IV-VI compound includes at least one of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the II-V compound includes at least one of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; the I-III-VI compound includes at least one of CuInS₂, CuInSe₂, and AgInS₂; the perovskite semiconductor material includes a doped or non-doped inorganic perovskite semiconductor, or an organic-inorganic hybrid perovskite semiconductor; the inorganic perovskite semiconductor has a general structure of AMX₃, where, A is a Cs⁺ ion, M is a divalent metal cation, and X is a halide anion; the organic-inorganic hybrid perovskite semiconductor has a general structure of BMX₃, where B is an organic amine cation, M is a divalent metal cation, and X is a halide anion; the divalent metal cation includes at least one of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺; the halide anion includes at least one of Cl⁻, Br⁻, and I⁻; the organic amine cation includes CH₃(CH₂)ₙ₋₂NH³⁺ or [NH₃(CH₂)ₙNH₃]²⁺, where n≥2.

Optionally, the light-emitting device further includes a hole injection layer disposed between the anode and the hole transport layer, a material of the hole injection layer includes TFB, CuPc, PVK, Poly-TPD, DNTPD, TCATA, TCCA, CBP, TPD, NPB, NPD, PEDOT:PSS, TAPC, MCC, F4-TCNQ, HATCN, 4,4′,4′-tris(N-3-methylphenyl-N-phenylamino) triphenylamine, polyaniline, a transition metal oxide, a transition metal sulfide, a transition metal stannide, doped graphene, undoped graphene, and C60; and/or
the light-emitting device further includes an electron transport layer and/or an electron injection layer disposed between the cathode and the light-emitting layer, a material of the electron transport layer and/or a material of the electron injection layer includes an inorganic material and/or an organic material; the inorganic material includes one or more of a doped or undoped zinc oxide, barium oxide, aluminum oxide, nickel oxide, titanium oxide, tin oxide, tantalum oxide, zirconium oxide, lithium titanium oxide, zinc aluminum oxide, zinc manganese oxide, zinc tin oxide, zinc lithium oxide, indium tin oxide, cadmium sulfide, zinc sulfide, molybdenum sulfide, tungsten sulfide, copper sulfide, zinc stannate, indium phosphide, gallium phosphide, copper indium sulfide, copper gallium sulfide, and barium titanate; a doping element of the doped or undoped zinc oxide includes one or more of aluminum, magnesium, lithium, manganese, yttrium, lanthanum, copper, nickel, zirconium, cerium, and gadolinium; the organic material includes one or more of a quinoxaline compound, an imidazole compound, a triazine compound, a fluorene-containing compound, and a hydroxyquinoline compound.

Correspondingly, the present disclosure further provides a method for preparing a light-emitting device including:
providing a light-emitting device preform and a composite material above; and
depositing the composite material on the light-emitting device preform to form a hole transport layer.

Optionally, after depositing the composite material on the light-emitting device preform and before the hole transport layer is formed, the method further includes: ultraviolet light irradiating for 2 to 10 minutes.

Optionally, depositing the composite material on the light-emitting device preform includes:
providing a solvent and the composite material, and mixing the solvent and the composite material to obtain a film-forming solution; and
depositing the film-forming solution on the light-emitting device preform to form the hole transport layer.

Optionally, a concentration of the composite material in the film-forming solution ranges from 4 mg/mL to 10 mg/mL; and/or
the solvent includes a non-polar organic solvent, and the non-polar organic solvent includes one or more of an alkane solvent, an alkene solvent, and an aromatic hydrocarbon solvent. The alkane solvent includes one or more of n-hexane, n-heptane, n-octane, cyclohexane, cycloheptane, chloroform, tetradecane, and cyclooctane; the alkene solvent includes one or more of 1-decene, 1-dodecene, 1-tetradecene, and 1-hexadecene; and the aromatic hydrocarbon solvent includes one or more of benzene, toluene, chlorobenzene, and xylene.

The voltage stabilizer in the composite material is a substituted aromatic ketone, which has good conjugation characteristics and electron delocalization, so that the composite material of the present disclosure has good electron affinity. In addition, the composite material of the present disclosure has good π-π stacking effect between molecules, so that the composite material of the present disclosure has good charge transport performance. When the composite material of the present disclosure is applied to the hole transport layer of the light-emitting device, based on the strong conjugation effect and electron delocalization of the voltage stabilizer molecules in the composite material, the voltage stabilizer may absorb the energy of the electrons by excitation or ionization, especially absorb the energy of high-energy electrons induced by electrons aggregation, and greatly weaken the kinetic energy of the high-energy electrons and reduce the number of the high-energy electrons, thereby reducing the damage of the electrons to the material of the hole transport layer, and improving the ability of the material of the hole transport layer to resist the damage of the electrons.

### BRIEF DESCRIPTION OF DRAWINGS

In order to clearly illustrate the technical solutions in the embodiments of the present disclosure, the following briefly describes the drawings that need to be used in the embodiments of the present disclosure, obviously, the following drawings are only some embodiments of the present disclosure, and for those skilled in the art, based on these drawings, other drawings may be obtained without creative work.

FIG. 1 is a flow chart of a method for preparing a light-emitting device;

FIG. 2 is a working voltage curve of a single electron device;

FIG. 3 is a J-V curve of a single electron device;

FIG. 4 is a working voltage curve of a single hole device;

FIG. 5 is a J-V curve of a single hole device;

FIG. 6 is an EL spectrum of a quantum dot light-emitting diode;

FIG. 7 is an AFM test diagram of a hole transport layer of a quantum dot light-emitting diode provided by the Example 2 of the present disclosure;

FIG. 8 is an AFM test diagram of a hole transport layer of a quantum dot light-emitting diode provided by the Comparative Example of the present disclosure;

FIG. 9 is an AFM test diagram of a quantum dot light-emitting layer of a quantum dot light-emitting diode provided by the Example 2 of the present disclosure;

FIG. 10 is an AFM test diagram of a quantum dot light-emitting layer of a quantum dot light-emitting diode provided by the Comparative Example of the present disclosure.

### EMBODIMENTS OF THE PRESENT DISCLOSURE

The technical solutions in the embodiments of the present disclosure will be clearly and completely described below in combination with the drawings in the embodiments of the present disclosure. Obviously, the described embodiments are only some of the embodiments of the present disclosure, rather than all the embodiments. Based on the embodiments in the present disclosure, all the other embodiments obtained by those skilled in the art without creative work are within the protection scope of the present disclosure.

In the present disclosure, “and/or” describes the association relationship of the associated objects, and indicates that three relationships may exist, for example, A and/or B may indicate that A exists alone, A and B exist simultaneously, and B exists alone. A and B may be singular or plural.

In the present disclosure, “at least one” means one or more, and “a plurality of” means two or more. “At least one”, “at least one of the following” or similar expressions mean any combination of the items, including any combination of single item or multiple items. For example, “at least one of a, b, or c”, or “at least one of a, b, and c” may represent a, b, c, a-b (i.e. a and b), a-c, b-c, or a-b-c, where a, b, and c may be a single item or multiple items.

The technical solution provided by the present disclosure will be described in detail below. It should be noted that the description order of the following embodiments does not limit the preferred order of the embodiments. In addition, in the description of the present disclosure, the term “comprising” means “including but not limited to”. Various embodiments of the present disclosure may exist in the form of a range; it should be understood that the description in the form of a range is only for convenience and brevity, and should not be understood as a rigid limitation on the scope of the present disclosure; therefore, it should be considered that the range description has specifically disclosed all possible sub-ranges and single values in the range.

The technical problem of the present disclosure is solved by the following technical solution.

The present disclosure provides a composite material including a hole transport material and a voltage stabilizer.

Moreover, the voltage stabilizer includes a substituted aromatic ketone, and at least one substituent of the aromatic ketone is an electron-donating group.

The molecular structure of the voltage stabilizer simultaneously gives the voltage stabilizer strong conjugation effect and strong electron delocalization performance, so that the composite material of the present disclosure has good electron affinity capacity. In addition, the composite material of present disclosure has good π-π stacking effect between molecules, so that the composite material of present disclosure has good charge transport performance (hole transport performance).

In some embodiments, the electron-donating group may include one or more of a hydroxyl, an alkoxy, a phenoxy, a benzyloxy, and an acyloxy.

In some embodiments, the voltage stabilizer may include a substituted aromatic ketone having 2 to 5 benzene ring structures. The substituted aromatic ketone having 2 to 5 benzene ring structures may include one or more of 4-allyloxy-2-hydroxybenzophenone, 2-hydroxy-4-(methacryloyloxy)benzophenone, 4′-phenoxyacetophenone, 4′-benzyloxy-2′-hydroxyacetophenone, 5,5′-methylenebis(2-hydroxy-4-methoxybenzophenone), and 4-hydroxy-4′-phenoxybenzophenone. When the voltage stabilizer includes the above substances, the conjugated structure in the molecular structure of the voltage stabilizer may greatly improve the electron affinity of the voltage stabilizer molecules, thereby improving the electron affinity efficiency of the voltage stabilizer. Based on the strong conjugation effect and electron delocalization of the voltage stabilizer molecules in the composite material, the voltage stabilizer may absorb the energy of the electrons by excitation or ionization, and may especially absorb the energy of high-energy electrons induced by electrons aggregation, and greatly weaken the kinetic energy of the high-energy electrons and reduce the number of the high-energy electrons, thereby reducing the damage of the electrons to the material of the hole transport layer, and improving the ability of the material of the hole transport layer to resist the damage of the electrons.

In at least one preferred embodiment, the voltage stabilizer may be 4-allyloxy-2-hydroxybenzophenone.

In some embodiments, a mass ratio of the voltage stabilizer to the hole transport material may be 1:(2-20). Specifically, the mass ratio of the voltage stabilizer to the hole transport material may be 1:2, 1:3, 1:4, 1:5, 1:6, 1:7, 1:8, 1:9, 1:10, 1:11, 1:12, 1:13, 1:14, 1:15, 1:16, 1:17, 1:18, 1:19, 1:20, etc. Within the ratio range, the composite material may have a higher electron affinity, and the composite material may have a better n-n stacking effect between molecules, thereby making the composite material have a good hole transport performance.

In some embodiments, the hole transport material may include at least one of TFB, CuPc, PVK, Poly-TPD, DNTPD, TCATA, TCCA, CBP, TPD, NPB, NPD, PEDOT:PSS, TAPC, MCC, F4-TCNQ, HATCN, 4,4,4′-tris(N-3-methylphenyl-N-phenylamino) triphenylamine, polyaniline, a transition metal oxide, a transition metal sulfide, a transition metal stannide, doped graphene, undoped graphene, and C60.

In addition, the present disclosure further provides a preparation method for the composite material, the method includes the following steps:
providing a hole transport material and a voltage stabilizer, mixing the hole transport material and the voltage stabilizer to obtain a composite material.

The hole transport material, the voltage stabilizer, and the ratio of the two are as described above and will not be repeated herein.

In some embodiments, the method for obtaining the composite material includes: providing a hole transport material and a voltage stabilizer, adding the hole transport material and the voltage stabilizer into an organic solvent, stirring at 40-60 °C for 2-4 h, and drying to obtain the composite material. Thus, stirring at 40-60 °C for 2-4 h may rapidly and uniformly disperse and mix the hole transport material and the voltage stabilizer.

In some embodiments, the organic solvent is a non-polar organic solvent. The non-polar organic solvent includes one or more of an alkane solvent, an alkene solvent, and an aromatic hydrocarbon solvent. The alkane solvent includes one or more of n-hexane, n-heptane, n-octane, cyclohexane, cycloheptane, chloroform, tetradecane, and cyclooctane. The alkene solvent includes one or more of 1-decene, 1-dodecene, 1-tetradecene, and 1-hexadecene. The aromatic hydrocarbon solvent includes one or more of benzene, toluene, chlorobenzene, and xylene. The non-polar organic solvent may make the composite material sufficiently uniformly dispersed.

Moreover, the present disclosure further provides a light-emitting device including a hole transport layer, and a material of the hole transport layer includes the composite material.

The material of the hole transport layer of the light-emitting device includes the composite material, the composite material has a high electron affinity, and the composite material has a good n-n stacking effect between molecules, so that the hole transport layer has a good hole transport performance. In addition, the hole transport layer of the light-emitting device has a strong ability to resist electron destruction based on the strong ability of the composite material to resist electron destruction.

In some embodiments, the light-emitting device may be one of a light-emitting diode, a solar cell, and a photodetector.

In some embodiments, the light-emitting device may be a light-emitting diode, which may be one of an organic light-emitting diode (OLED), a quantum dot light-emitting diode (QLED), and a micro light-emitting diode (Micro-LED). Further, the light-emitting diode of the present disclosure may be a light-emitting diode in a forward-structure or a light-emitting diode in an inverted structure, and the light-emitting diode may be any one of a light-emitting diode in a top emission structure, a light-emitting diode in a bottom emission structure, and a light-emitting diode in a double-side emission structure.

Preferably, the light-emitting diode may be a quantum dot light-emitting diode.

The material of the hole transport layer of the quantum dot light-emitting diode in the present disclosure is the composite material provided by the present disclosure. Based on the strong conjugation effect and electron delocalization of the voltage stabilizer molecules, the voltage stabilizer may absorb the energy of electrons, especially high-energy electrons, in the form of excitation or ionization, thereby greatly weaken the kinetic energy of the high-energy electrons, and reduce the number of the high-energy electrons, thereby reducing the damage of the electrons to the material of the hole transport layer and improving the stability of the quantum dot light-emitting diode. In addition, the composite material has high electron affinity and may make the composite material molecules have good n-n stacking effect, so that the hole transport layer has good hole transport performance.

Moreover, the nonlinear conductive characteristic of the voltage stabilizer (for example, 4-allyloxy-2-hydroxybenzophenone) in the material of the hole transport layer (the composite material) may reduce the degree of electric field distortion of the quantum dot light-emitting diode, reduce or even avoid the accumulation of excess electrons between the hole transport layer and the light-emitting layer, thereby reducing the damage of the electric field distortion to the material in the quantum dot light-emitting diode, and further improving the stability of the quantum dot light-emitting diode. Meanwhile, the reduction of the accumulation of the electrons between the hole transport layer and the light-emitting layer also reduces the non-radiative recombination (for example, auger recombination) in the quantum dot light-emitting diode, thereby improving the efficiency of the quantum dot light-emitting diode.

In some embodiments, in addition to the hole transport layer, the quantum dot light-emitting diode may further include an anode, a hole injection layer, a quantum dot light-emitting layer, an electron transport layer and a cathode which are arranged in a stack. In some embodiments, the quantum dot light-emitting diode may further include an electron injection layer and other common functional layers.

In some embodiments, a material of the hole injection layer may be selected from one or more of poly(3,4-ethylenedioxythiophene)-polystyrenesulfonate (PEDOT:PSS), 2,3,5,6-tetrafluoro-7,7′,8,8′-tetracyanoquinodimethane (F4-TCNQ), copper phthalocyanine (CuPc), 1,4,5,8,9,11-hexaazatriphenylenehexacarbonitrile (HATCN), NiOₓ, MoOₓ, WOₓ, CrOₓ, CuO, MoSₓ, MoSeₓ, WSₓ, WSeₓ, and CuS, where x is in a range from 1 to 3. In some embodiments, the hole transport layer may also be other metal chalcogenide compounds.

In some embodiments, a material of the light-emitting layer includes one or more of an organic light-emitting material and a quantum dot light-emitting material. The organic light-emitting material includes at least one of 4,4′-bis(N-carbazole)-1,1′-biphenyl:tris[2-(p-tolyl)pyridine-C2,N) iridium(III), 4,4′,4″-tris(carbazole-9-yl)triphenylamine:tris[2-(p-tolyl)pyridine-C2,N) iridium, a diaromatic anthracene derivative, a stilbene aromatic derivative, a pyrene derivative, a fluorene derivative, TBPe fluorescent material, TTPX fluorescent material, TBRb fluorescent material, and DBP fluorescent material. The quantum dot light-emitting material includes at least one of a single-structure quantum dot, a core-shell structure quantum dot, and a perovskite semiconductor material. A material of the single-structure quantum dot, a core material of the core-shell structure quantum dot and a shell material of the core-shell structure quantum dot respectively include at least one of an II-VI compound, an IV-VI compound, an II-V compound, and an I-III-VI compound. The II-VI compound includes at least one of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe. The IV-VI compound includes at least one of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe. The II-V compound includes at least one of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb. The I-III-VI compound includes at least one of CuInS₂, CuInSe₂, and AgInS₂. The perovskite semiconductor material includes a doped or non-doped inorganic perovskite semiconductor, or an organic-inorganic hybrid perovskite semiconductor. The inorganic perovskite semiconductor has a general structure of AMX₃, where, A is a Cs⁺ ion, M is a divalent metal cation, and X is a halide anion. The organic-inorganic hybrid perovskite semiconductor has a general structure of BMX₃, where B is an organic amine cation, M is a divalent metal cation, and X is a halide anion. The divalent metal cation includes at least one of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺. The halide anion includes at least one of Cl⁻, Br⁻, and I⁻. The organic amine cation includes CH₃(CH₂)ₙ₋₂NH³⁺ or [NH₃(CH₂)ₙNH₃]²⁺, where n≥2.

In some embodiments, a material of the electron transport layer includes an inorganic material and/or an organic material. The inorganic material includes one or more of doped or undoped zinc oxide, barium oxide, aluminum oxide, nickel oxide, titanium oxide, tin oxide, tantalum oxide, zirconium oxide, lithium titanium oxide, zinc aluminum oxide, zinc manganese oxide, zinc tin oxide, zinc lithium oxide, indium tin oxide, cadmium sulfide, zinc sulfide, molybdenum sulfide, tungsten sulfide, copper sulfide, zinc stannate, indium phosphide, gallium phosphide, copper indium sulfide, copper gallium sulfide, and barium titanate. a doping element of the doped or undoped zinc oxide includes one or more of aluminum, magnesium, lithium, manganese, yttrium, lanthanum, copper, nickel, zirconium, cerium, and gadolinium. The organic material includes one or more of a quinoxaline compound, an imidazole compound, a triazine compound, a fluorene-containing compound, and a hydroxyquinoline compound.

In some embodiments, a material of the anode and a material of the cathode respectively independently include one or more of a metal, a carbon material, and a metal oxide. The metal includes one or more of Al, Ag, Cu, Mo, Au, Ba, Ca, Yb, and Mg. The carbon material includes one or more of graphite, carbon nanotube, graphene, and carbon fiber. The metal oxide includes a doped or undoped metal oxide, which includes one or more of ITO, FTO, ATO, AZO, GZO, IZO, MZO, and AMO. The anode and the cathode may further include a composite electrode with metal sandwiched between doped or undoped transparent metal oxides. The composite electrode includes one or more of AZO/Ag/AZO, AZO/Al/AZO, ITO/Ag/ITO, ITO/A/ITO, ZnO/Ag/ZnO, ZnO/Al/ZnO, ZnS/Ag/ZnS, ZnS/Al/ZnS, TiO₂/Ag/TiO₂, and TiO₂/Al/TiO₂.

In some embodiments, the light-emitting device further includes an electron injection layer disposed between the cathode and the light-emitting layer. A material of the electron injection layer includes an inorganic material and/or an organic material. The inorganic material includes one or more of a doped or undoped zinc oxide, barium oxide, aluminum oxide, nickel oxide, titanium oxide, tin oxide, tantalum oxide, zirconium oxide, lithium titanium oxide, zinc aluminum oxide, zinc manganese oxide, zinc tin oxide, zinc lithium oxide, indium tin oxide, cadmium sulfide, zinc sulfide, molybdenum sulfide, tungsten sulfide, copper sulfide, zinc stannate, indium phosphide, gallium phosphide, copper indium sulfide, copper gallium sulfide, and barium titanate. A doping element of the doped or undoped zinc oxide includes one or more of aluminum, magnesium, lithium, manganese, yttrium, lanthanum, copper, nickel, zirconium, cerium, and gadolinium. The organic material includes one or more of a quinoxaline compound, an imidazole compound, a triazine compound, a fluorene-containing compound, and a hydroxyquinoline compound.

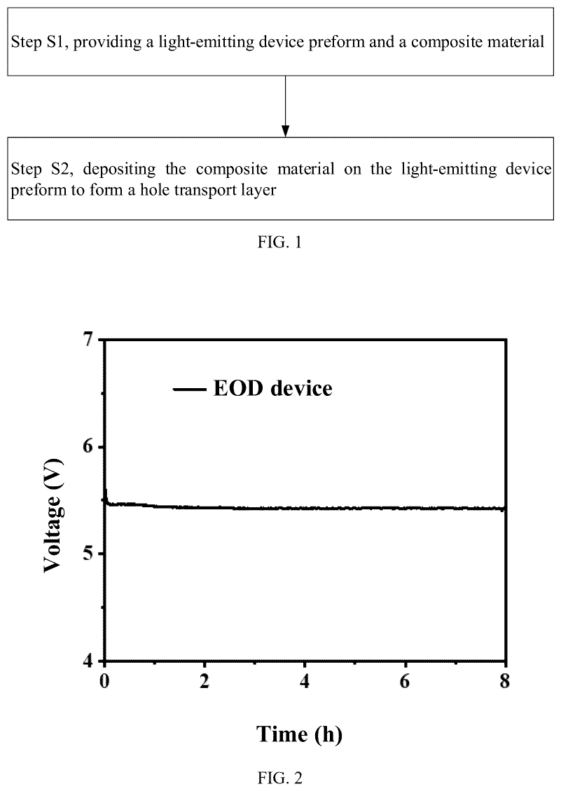

Moreover, referring to FIG. 1, the present disclosure further provides a method for preparing a light-emitting device, the method includes:
Step S1, providing a light-emitting device preform and a composite material; and
Step S2, depositing the composite material on the light-emitting device preform to form a hole transport layer.

The light-emitting device preform refers to a semi-finished product of a light-emitting device need to be deposited with a hole transport layer. The light-emitting device preform may include different layer structures according to different types of devices. In some embodiments, the light-emitting device may be a light-emitting diode of a forward-structure, and the light-emitting device preform may include an anode and a hole injection layer which are sequentially stacked. In some embodiments, the light-emitting device may be a light-emitting diode of an inverted structure, and the light-emitting device may include a cathode, an electron transport layer, and a light-emitting layer which are sequentially stacked.

A method for depositing the composite material on the light-emitting device preform may be a chemical method or a physical method. The chemical method includes a chemical vapor deposition, a successive ionic layer adsorption and reaction, an anodic oxidation, an electrolytic deposition, and a co-precipitation. The physical method includes a physical coating and a solution method. The physical coating includes a thermal evaporation coating, an electron beam evaporation coating, magnetron sputtering, a multi-arc ion coating, a physical vapor deposition, an atomic layer deposition, a pulsed laser deposition, and the like. The solution method may be a spin coating method, a printing method, an inkjet printing method, a blade coating method, a dip coating method, an immersion method, a spraying method, a rolling method, a casting method, a slot coating method, a stripe coating method, and the like.

In at least one embodiment, the method for disposing the composite material on the light-emitting device preform is a solution method. The method for depositing the composite material on the light-emitting device preform includes:
providing a solvent and the composite material, and mixing the solvent and the composite material to obtain a film-forming solution; and
disposing the film-forming solution on the light-emitting device preform by the solution method to form the hole transport layer.

In some embodiments, a method for mixing the solvent and the composite material is stirring at 40-60 °C for 2-4 h, so that the composite material may be rapidly and uniformly dispersed in the solvent.

In some embodiments, the solvent may be a non-polar organic solvent. The non-polar organic solvent includes one or more of an alkane solvent, an alkene solvent, and an aromatic hydrocarbon solvent. The alkane solvent includes one or more of n-hexane, n-heptane, n-octane, cyclohexane, cycloheptane, chloroform, tetradecane, and cyclooctane. The alkene solvent includes one or more of 1-decene, 1-dodecene, 1-tetradecene, and 1-hexadecene. The aromatic hydrocarbon solvent includes one or more of benzene, toluene, chlorobenzene, and xylene. The non-polar organic solvent may make the composite material be uniformly dispersed, improve the film uniformity of the composite material, and the non-polar solvent may not dissolve and damage other film layers of the light-emitting device preform.

In at least one preferred embodiment, the solvent may be chlorobenzene, the hole transport material in the composite material may be TFB, and the voltage stabilizer in the composite material may be 4-allyloxy-2-hydroxybenzophenone (AOHBP). Thus, a hole transport layer and a light-emitting device with excellent hole transport performance may be prepared.

In some embodiments, a concentration of the composite material in the film-forming solution ranges from 4 mg/mL to 10 mg/mL. In the concentration range, the film-forming solution has good film-forming property, and the prepared hole transport layer has good conductivity, good hole injection performance, and good stability, so that the prepared light-emitting device has high luminous efficiency and long lifetime.

The film-forming solution may also be prepared by the following method: providing a solvent; adding the hole transport material and the voltage stabilizer to the solvent to obtain a film-forming solution. It should be understood that the addition order of the hole transport material and the voltage stabilizer is not limited, and the hole transport material may be added first and then the voltage stabilizer, or the voltage stabilizer may be added first and then the hole transport material, or the hole transport material and the voltage stabilizer may be added to the solvent at the same time.

In at least one specific embodiment, the preparation of the film-forming solution may include: dispersing 160 mg of TFB in 20 mL of chlorobenzene, heating at 60 °C for 6 hours to prepare an 8 mg/mL TFB chlorobenzene solution; and adding different amounts of AOHBP to 1 mL of the above 8 mg/mL TFB chlorobenzene solution to prepare three film-forming solutions with the mass ratio of AOHBP to TFB being 1:15, 1:10 and 1:5, respectively.

In some embodiments, to form the hole transport layer, the method for preparing the light-emitting device may further include a process step of high-temperature annealing.

In some embodiments, after the composite material is deposited on the light-emitting device preform and before the hole transport layer is formed, the method further includes: ultraviolet light irradiating the film layer formed by the film-forming solution.

Under ultraviolet (UV) irradiation, the voltage stabilizer molecules such as 4-allyloxy-2-hydroxybenzophenone may undergo hydrogen absorption reaction (free radical reaction mechanism) with hydrogen donors such as C—H bond on the organic matter, and therefore, the voltage stabilizer molecules such as 4-allyloxy-2-hydroxybenzophenone may crosslink the hole transport material molecules under photo-initiation, so that the prepared hole transport layer has good film layer uniformity, and the surface of the hole transport layer has a smoother morphology and lower roughness.

In some embodiments, a time of the ultraviolet light irradiating ranges from 2 minutes to 10 minutes. In the range, the hydrogen absorption reaction between the hole transport material and the voltage stabilizer molecules may be effectively promoted, and the hole transport layer with good film layer uniformity, smoother surface morphology and lower roughness may be prepared.

The hole transport material may be preferably a polymer having benzylic hydrogen and tertiary hydrogen, such as TFB (benzylic hydrogen and tertiary hydrogen present on the side chain of TFB), and the voltage stabilizer molecules may react with the benzylic hydrogen and the tertiary hydrogen in the polymer to form relatively stable free radicals, so that the free radical reaction efficiency is improved.

In some embodiments, the light-emitting device is a quantum dot light-emitting diode in a forward-structure, and the quantum dot light-emitting layer may be spread more uniformly on the hole transport layer based on the good film uniformity of the hole transport layer. Under the same process conditions, the thickness of the quantum dot light-emitting layer may also be reduced. Therefore, the improvement of the film uniformity of the hole transport layer may effectively improve the film uniformity of the quantum dot light-emitting layer and reduce the thickness of the quantum dot light-emitting layer. On the one hand, the improvement of the film uniformity of the quantum dot light-emitting layer ensures that the quantum dot light-emitting diode has high electroluminescence (EL) efficiency; and on another hand, the reduction of the thickness of the quantum dot light-emitting layer may endow the quantum dot light-emitting diode with high device performance.

### Example 1

This Example provides a composite material including a hole transport material and a voltage stabilizer, where the hole transport material is TFB, the voltage stabilizer is AOHBP, and a mass ratio of AOHBP to TFB is 1:15.

In this Example, a preparation method for the composite material includes: the voltage stabilizer AOHBP and the hole transport material TFB in a mass ratio of 1:15 were provided, and were uniformly mixed to obtain the composite material.

In addition, this Example further provides a quantum dot light-emitting diode including an anode, a hole injection layer, a hole transport layer, a quantum dot light-emitting layer, an electron transport layer and a cathode which are sequentially stacked.

A thickness of the anode is 100 nm, and a material of the anode is ITO; a thickness of the hole injection layer is 25 nm, and a material of the hole injection layer is PEDOT:PSS; a thickness of the hole transport layer is 25 nm, and a material of the hole transport layer is the composite material provided in this Example; a thickness of the quantum dot light-emitting layer is 25 nm, and a material of the quantum dot light-emitting layer is CdZnSe/ZnSe/Cd_{0.6}ZnS₂/ZnSe; a thickness of the electron transport layer is 30 nm, and a material of the electron transport layer is ZnMgO; and a thickness of the cathode is 100 nm, and a material of the cathode is Ag.

In addition, this Example further provides a preparation method for the quantum dot light-emitting diode, and the method includes the following steps:
Step S101, a glass substrate provided with an ITO anode was provided, the glass substrate was placed in a glass dish containing an ethanol solvent, the solvent in the glass dish was sequentially replaced with acetone, deionized water and ethanol, the glass substrate was ultrasonically treated for 20 minutes respectively, the glass substrate was then dried by blowing with a nitrogen gun, the glass substrate was then placed in an oxygen plasma environment for continuous cleaning for 10 minutes, and the surface of the glass substrate was treated with ultraviolet-ozone for 15 minutes;
Step S102: a PEDOT:PSS solution was spin coated on the surface of the ITO anode at a spin speed of 3500 r/min for 30 seconds; after spin coating, the glass substrate on which the PEDOT:PSS solution was spin coated was annealed in the air at an annealing temperature of 150 °C for 30 minutes to obtain a hole injection layer with a thickness of 25 nm; and the glass substrate on which the hole injection layer was formed was quickly transferred into a glove box in a nitrogen atmosphere after the annealing;
Step 3: a film-forming solution of the hole transport layer was spin coated on the surface of the hole transport layer, a solvent of the film-forming solution was chlorobenzene, a solute of the film-forming solution was the composite material provided in this Example, a spin coated speed was 3000 r/min, and a spin coated time was being 30 seconds; after the spin coated, a film formed by the film-forming solution was irradiated under an ultraviolet lamp (360 nm) for 5 minutes, and then annealed at an annealing temperature of 180 °C for 30 minutes to obtain a hole transport layer with a thickness of 25 nm;
Step 4: a CdZnSe/ZnSe/Cd_{0.6}ZnS₂/ZnSe quantum dot solution was spin coated on the hole transport layer at a spin speed of 2000 r/min for 30 seconds; and the glass substrate on which the CdZnSe/ZnSe/Cd_{0.6}ZnS₂/ZnSe quantum dot solution was spin coated was annealed in the glove box at an annealing temperature of 60 °C for 5 minutes to obtain a quantum dot light-emitting layer with a thickness of 25 nm;
Step 5: a ZnMgO ethanol solution with a concentration of 30 mg/mL was spin coated on the quantum dot light-emitting layer at a spin speed of 3000 r/min for 30 seconds to obtain an electron transport layer with a thickness of 30 nm;
Step 6: the glass substrate on which the electron transport layer was prepared was placed into a vacuum cavity, silver was evaporated on the electron transport layer to obtain a cathode with a thickness of 100 nm, and a quantum dot light-emitting diode was obtained by packaging.

In order to perform testing, this Example further provides a single electron device (EOD) and a single hole device (HOD) corresponding to the quantum dot light-emitting diode.

The single electron device includes an anode, a quantum dot light-emitting layer, an electron transport layer, and a cathode which are sequentially stacked.

A thickness of the anode is 100 nm, and a material of the anode is ITO; a thickness of the quantum dot light-emitting layer is 25 nm, and a material of the quantum dot light-emitting layer is CdZnSe/ZnSe/Cd_{0.6}ZnS₂/ZnSe; a thickness of the electron transport layer is 30 nm, and a material of the electron transport layer is ZnMgO; and a thickness of the cathode is 100 nm, and a material of the cathode is Ag.

The single hole device includes an anode, a hole injection layer, a hole transport layer, a quantum dot light-emitting layer, and a cathode which are sequentially stacked.

A thickness of the anode is 100 nm, and a material of the anode is ITO; a thickness of the hole injection layer is 25 nm, and a material of the hole injection layer is PEDOT:PSS; a thickness of the hole transport layer is 25 nm, and a material of the hole transport layer is the composite material provided in this Example; a material of the quantum dot light-emitting layer is CdZnSe/ZnSe/Cd_{0.6}ZnS₂/ZnSe; and a thickness of the cathode is 100 nm, and a material of the cathode is Ag.

Correspondingly, this Example further provides a preparation method for the single-electron device and a preparation method for the single-hole device.

The preparation method for the single-electron device includes the following steps:
Step S201, a glass substrate provided with an ITO anode was provided, the glass substrate was placed in a glass dish containing an ethanol solvent, the solvent in the glass dish was sequentially replaced with acetone, deionized water and ethanol, the glass substrate was ultrasonically treated for 20 minutes respectively, the glass substrate was then dried by a nitrogen gun, the glass substrate was then placed in an oxygen plasma environment for continuous cleaning for 10 minutes, and the surface of the glass substrate was treated by ultraviolet-ozone for 15 minutes;
Step S202, a CdZnSe/ZnSe/Cd_{0.6}ZnS₂/ZnSe quantum dot solution was spin-coated on the ITO anode at a spin speed of 2000 r/min for 30 seconds; and the glass substrate on which the CdZnSe/ZnSe/Cd_{0.6}ZnS₂/ZnSe quantum dot solution was spin-coated was annealed in a glove box at an annealing temperature of 60 °C for 5 minutes after the spin coating was completed, so as to prepare a quantum dot light-emitting layer with a thickness of 25 nm.
Step 3, a ZnMgO ethanol solution with a concentration of 30 mg/mL was spin-coated on the quantum dot light-emitting layer at a spin speed of 3000 r/min for 30 seconds, so as to prepare an electron transport layer with a thickness of 30 nm.
Step 4, the glass substrate provided with the electron transport layer was placed in a vacuum chamber, silver was evaporated on the electron transport layer, a cathode with a thickness of 100 nm was obtained, and a single-electron device was obtained.

The preparation method for the single-hole device includes the following steps:
Step S301, a glass substrate provided with an ITO anode was provided, the glass substrate was placed in a glass dish containing an ethanol solvent, the solvent in the glass dish was sequentially replaced with acetone, deionized water and ethanol, the glass substrate was ultrasonically treated for 20 minutes respectively, the glass substrate was then dried by a nitrogen gun, the glass substrate was then placed in an oxygen plasma environment for continuous cleaning for 10 minutes, and the surface of the glass substrate was treated by ultraviolet-ozone for 15 minutes.
Step 2: a PEDOT:PSS solution was spin coated on the surface of the ITO anode at a spin speed of 3500 r/min for 30 seconds; after spin coating, the glass substrate spin coated with the PEDOT:PSS solution was annealed in air at an annealing temperature of 150 °C for 30 minutes to obtain a hole injection layer with a thickness of 25 nm; and the glass substrate with the hole injection layer formed thereon was quickly transferred to a glove box filled with nitrogen;
Step 3: a film-forming solution of the hole transport layer was spin coated on the surface of the hole injection layer at a spin speed of 3000 r/min for 30 seconds, where the solvent of the film-forming solution was chlorobenzene, and the solute of the film-forming solution was the composite material provided in this Example; after spin coating, the film layer formed by the film-forming solution was irradiated under an ultraviolet lamp (360 nm) for 5 minutes, and then annealing at an annealing temperature of 180 °C for 30 minutes to obtain a hole transport layer with a thickness of 25 nm;
Step 4: a CdZnSe/ZnSe/Cd_{0.6}ZnS₂/ZnSe quantum dot solution was spin coated on the hole transport layer at a spin speed of 2000 r/min for 30 seconds; and the glass substrate spin coated with the CdZnSe/ZnSe/Cd_{0.6}ZnS₂/ZnSe quantum dot solution was annealed in the glove box at an annealing temperature of 60 °C for 5 minutes to obtain a quantum dot light-emitting layer with a thickness of 25 nm;
Step 5: the glass substrate with the quantum dot light-emitting layer prepared thereon was placed into a vacuum chamber, silver was evaporated on the quantum dot light-emitting layer to obtain a cathode with a thickness of 100 nm, and obtaining a single-electron device.

### Example 2

This Example provides a composite material including a hole transport material and a voltage stabilizer, where the hole transport material is TFB, the voltage stabilizer is AOHBP, and a mass ratio of AOHBP to TFB is 1:10.

In this Example, a preparation method for the composite material includes: the voltage stabilizer AOHBP and the hole transport material TFB in a mass ratio of 1:10 were provided, and were uniformly mixed to obtain the composite material.

In addition, this Example further provides a quantum dot light-emitting diode, which is only different from the quantum dot light-emitting diode provided by Example 1 in that the material in the hole transport layer of the quantum dot light-emitting diode provided by Example 1 was replaced with the composite material provided by this Example, and the remaining parts are the same as those of the quantum dot light-emitting diode provided by Example 1.

In addition, this Example further provides a preparation method for the quantum dot light-emitting diode, which is only different from Step 3 of the preparation method for the quantum dot light-emitting diode provided by Example 1 in that the solute of the film-forming solution in Step 3 of the preparation method for the quantum dot light-emitting diode provided by Example 1 was replaced with the composite material provided by this Example.

In order to perform testing, this Example further provides a single hole device (HOD) corresponding to the quantum dot light-emitting diode.

The single hole device is only different from the single hole device provided by Example 1 in that the material in the hole transport layer of the single hole device provided by Example 1 was replaced with the composite material provided by this Example, and the remaining parts are the same as those of the single hole device provided by Example 1.

Since the single electron device corresponding to the quantum dot light-emitting diode in this Example is the same as the single electron device provided by Example 1, this Example did not additionally provide the single electron device.

Correspondingly, this Example further provides a preparation method for the single hole device.

The preparation method for the single hole device is only different from the preparation method for the single hole device provided by Example 1 in that the solute of a film forming-solution in Step 3 of the preparation method for the single hole device provided by Example 1 was replaced with the composite material provided by this Example, and the remaining steps are the same as those of the preparation method for the single hole device provided by Example 1.

### Example 3

This Example provides a composite material including a hole transport material and a voltage stabilizer, where the hole transport material is TFB, the voltage stabilizer is AOHBP, and a mass ratio of AOHBP to TFB is 1:5.

In this Example, a preparation method for the composite material includes: the voltage stabilizer AOHBP and the hole transport material TFB at a mass ratio of 1:5 were provided, and were uniformly mixed to obtain the composite material.

In addition, this Example further provides a quantum dot light-emitting diode, which is only different from the quantum dot light-emitting diode provided by Example 1 in that the material in the hole transport layer of the quantum dot light-emitting diode provided by Example 1 was replaced with the composite material provided by this Example, and the remaining parts are the same as those of the quantum dot light-emitting diode provided by Example 1.

In addition, this Example further provides a preparation method for the quantum dot light-emitting diode, which is only different from Step 3 of the preparation method for the quantum dot light-emitting diode provided by Example 1 in that the solute of the film-forming solution in Step 3 of the preparation method for the quantum dot light-emitting diode provided by Example 1 was replaced with the composite material provided by this Example, and the remaining steps are the same as those of the preparation method for the quantum dot light-emitting diode provided by Example 1.

In order to perform testing, this Example further provides a single hole device (HOD) corresponding to the quantum dot light-emitting diode.

The single hole device is only different from the single hole device provided by Example 1 in that the material in the hole transport layer of the single hole device provided by Example 1 was replaced with the composite material provided by this Example, and the remaining parts are the same as those of the single hole device provided by Example 1.

Since the single electron device corresponding to the quantum dot light-emitting diode in this Example is the same as the single electron device provided by Example 1, the Example did not additionally provide the single electron device.

Correspondingly, this Example further provides a preparation method for the single hole device.

The preparation method for the single hole device is only different from the preparation method for the single hole device provided by Example 1 in that a solute of a film forming-solution in Step 3 of the preparation method for the single hole device provided by Example 1 was replaced with the composite material provided by this Example, and the remaining steps are the same as those of the preparation method for the single hole device provided by Example 1.

### Example 4

This Example provides a composite material, including a hole transport material and a voltage stabilizer, where the hole transport material is TFB, the voltage stabilizer is 5,5′-methylenebis(2-hydroxy-4-methoxybenzophenone), and a mass ratio of 5,5′-methylenebis(2-hydroxy-4-methoxybenzophenone) to TFB is 1:10.

In this Example, a preparation method for the composite material includes: the voltage stabilizer 5,5′-methylenebis(2-hydroxy-4-methoxybenzophenone) and the hole transport material TFB in a mass ratio of 1:10 were provided, and were uniformly mixed to obtain the composite material.

In addition, this Example further provides a quantum dot light-emitting diode, which is only different from the quantum dot light-emitting diode provided by the Example 1 in that the material in the hole transport layer of the quantum dot light-emitting diode provided in the Example 1 was replaced by the composite material provided in this Example, and the remaining parts are the same as those of the quantum dot light-emitting diode provided by Example 1.

In addition, this Example further provides a preparation method for the quantum dot light-emitting diode, which is only different from Step 3 of the preparation method for the quantum dot light-emitting diode provided by Example 1 in that the solute of the film forming-solution in Step 3 of the preparation method for the quantum dot light-emitting diode provided by Example 1 was replaced with the composite material provided by this Example.

In order to perform testing, this Example further provides a single hole device (HOD) corresponding to the quantum dot light-emitting diode.

The single hole device is the same as the single hole device provided by the Example 1 in that the material in the hole transport layer of the single hole device provided by the Example 1 was replaced with the composite material provided by this Example, and the remaining parts are the same as those of the single hole device provided by Example 1.

Since the single electron device corresponding to the quantum dot light-emitting diode in this Example is the same as the single electron device provided in the Example 1, this Example did not additionally provide the single electron device.

Correspondingly, this Example further provides a preparation method for the single hole device.

The preparation method for the single hole device is the same as the step of the preparation method for the single hole device provided by Example 1 except that the solute of the film forming-solution in Step 3 is replaced by the composite material provided in the Example.

### Example 5

This Example provides a composite material, including a hole transport material and a voltage stabilizer, where the hole transport material is TFB, the voltage stabilizer is 5,5′-methylenebis(2-hydroxy-4-methoxybenzophenone), and a mass ratio of 5,5′-methylenebis(2-hydroxy-4-methoxybenzophenone) to TFB is 1:10.

In this Example, a preparation method for the composite material includes: the voltage stabilizer 5,5′-methylenebis(2-hydroxy-4-methoxybenzophenone) and the hole transport material TFB in a mass ratio of 1:10 were provided, and were uniformly mixed to obtain the composite material.

In addition, this Example further provides a quantum dot light-emitting diode, which is only different from the quantum dot light-emitting diode provided by the Example 1 in that the material in the hole transport layer of the quantum dot light-emitting diode provided in the Example 1 was replaced by the composite material provided in this Example, and the remaining parts are the same as those of the quantum dot light-emitting diode provided by Example 1.

In addition, this Example further provides a preparation method for the quantum dot light-emitting diode, which is only different from Step 3 of the preparation method for the quantum dot light-emitting diode provided by Example 1 in that the solute of the film forming-solution in Step 3 of the preparation method for the quantum dot light-emitting diode provided by Example 1 was replaced with the composite material provided by this Example.

In order to perform testing, this Example further provides a single hole device (HOD) corresponding to the quantum dot light-emitting diode.

The single hole device is the same as the single hole device provided by the Example 1 in that the material in the hole transport layer of the single hole device provided by the Example 1 was replaced with the composite material provided by this Example, and the remaining parts are the same as those of the single hole device provided by Example 1.

Since the single electron device corresponding to the quantum dot light-emitting diode in this Example is the same as the single electron device provided in the Example 1, this Example did not additionally provide the single electron device.

Correspondingly, this Example further provides a preparation method for the single hole device.

The preparation method for the single hole device is the same as the step of the preparation method for the single hole device provided by Example 1 except that the solute of the film forming-solution in Step 3 is replaced by the composite material provided in the Example.

### Example 6

This Example provides a composite material, including a hole transport material and a voltage stabilizer, where the hole transport material is TFB, the voltage stabilizer is 2-hydroxy-4-methoxybenzophenone, and a mass ratio of 2-hydroxy-4-methoxybenzophenone to TFB is 1:10.

In this Example, a preparation method for the composite material includes: the voltage stabilizer 2-hydroxy-4-methoxybenzophenone and the hole transport material TFB in a mass ratio of 1:10 were provided, and were uniformly mixed to obtain the composite material.

In addition, this Example further provides a quantum dot light-emitting diode, which is only different from the quantum dot light-emitting diode provided by the Example 1 in that the material in the hole transport layer of the quantum dot light-emitting diode provided in the Example 1 was replaced by the composite material provided in this Example, and the remaining parts are the same as those of the quantum dot light-emitting diode provided by Example 1.

In addition, this Example further provides a preparation method for the quantum dot light-emitting diode, which is only different from Step 3 of the preparation method for the quantum dot light-emitting diode provided by Example 1 in that the solute of the film forming-solution in Step 3 of the preparation method for the quantum dot light-emitting diode provided by Example 1 was replaced with the composite material provided by this Example.

In order to perform testing, this Example further provides a single hole device (HOD) corresponding to the quantum dot light-emitting diode.

The single hole device is the same as the single hole device provided by the Example 1 in that the material in the hole transport layer of the single hole device provided by the Example 1 was replaced with the composite material provided by this Example, and the remaining parts are the same as those of the single hole device provided by Example 1.

Since the single electron device corresponding to the quantum dot light-emitting diode in this Example is the same as the single electron device provided in the Example 1, this Example did not additionally provide the single electron device.

Correspondingly, this Example further provides a preparation method for the single hole device.

The preparation method for the single hole device is the same as the step of the preparation method for the single hole device provided by Example 1 except that the solute of the film forming-solution in Step 3 is replaced by the composite material provided in the Example.

### Example 7

This Example provides a composite material, including a hole transport material and a voltage stabilizer, where the hole transport material is TFB, the voltage stabilizer is 4′-phenoxyacetophenone, and a mass ratio of 4′-phenoxyacetophenone to TFB is 1:10.

In this Example, a preparation method for the composite material includes: the voltage stabilizer 4′-phenoxyacetophenone and the hole transport material TFB in a mass ratio of 1:10 were provided, and were uniformly mixed to obtain the composite material.

In addition, this Example further provides a quantum dot light-emitting diode, which is only different from the quantum dot light-emitting diode provided by the Example 1 in that the material in the hole transport layer of the quantum dot light-emitting diode provided in the Example 1 was replaced by the composite material provided in this Example, and the remaining parts are the same as those of the quantum dot light-emitting diode provided by Example 1.

In addition, this Example further provides a preparation method for the quantum dot light-emitting diode, which is only different from Step 3 of the preparation method for the quantum dot light-emitting diode provided by Example 1 in that the solute of the film forming-solution in Step 3 of the preparation method for the quantum dot light-emitting diode provided by Example 1 was replaced with the composite material provided by this Example.

In order to perform testing, this Example further provides a single hole device (HOD) corresponding to the quantum dot light-emitting diode.

The single hole device is the same as the single hole device provided by the Example 1 in that the material in the hole transport layer of the single hole device provided by the Example 1 was replaced with the composite material provided by this Example, and the remaining parts are the same as those of the single hole device provided by Example 1.

Since the single electron device corresponding to the quantum dot light-emitting diode in this Example is the same as the single electron device provided in the Example 1, this Example did not additionally provide the single electron device.

Correspondingly, this Example further provides a preparation method for the single hole device.

The preparation method for the single hole device is the same as the step of the preparation method for the single hole device provided by Example 1 except that the solute of the film forming-solution in Step 3 is replaced by the composite material provided in the Example.

### Example 8

This Example provides a composite material, including a hole transport material and a voltage stabilizer, where the hole transport material is TFB, the voltage stabilizer is 4′-benzyloxy-2′-hydroxyacetophenone, and a mass ratio of 4′-benzyloxy-2′-hydroxyacetophenone to TFB is 1:10.

In this Example, a preparation method for the composite material includes: the voltage stabilizer 4′-benzyloxy-2′-hydroxyacetophenone and the hole transport material TFB in a mass ratio of 1:10 were provided, and were uniformly mixed to obtain the composite material.

In addition, this Example further provides a quantum dot light-emitting diode, which is only different from the quantum dot light-emitting diode provided by the Example 1 in that the material in the hole transport layer of the quantum dot light-emitting diode provided in the Example 1 was replaced by the composite material provided in this Example, and the remaining parts are the same as those of the quantum dot light-emitting diode provided by Example 1.

In addition, this Example further provides a preparation method for the quantum dot light-emitting diode, which is only different from Step 3 of the preparation method for the quantum dot light-emitting diode provided by Example 1 in that the solute of the film forming-solution in Step 3 of the preparation method for the quantum dot light-emitting diode provided by Example 1 was replaced with the composite material provided by this Example.

In order to perform testing, this Example further provides a single hole device (HOD) corresponding to the quantum dot light-emitting diode.

The single hole device is the same as the single hole device provided by the Example 1 in that the material in the hole transport layer of the single hole device provided by the Example 1 was replaced with the composite material provided by this Example, and the remaining parts are the same as those of the single hole device provided by Example 1.

Since the single electron device corresponding to the quantum dot light-emitting diode in this Example is the same as the single electron device provided in the Example 1, this Example did not additionally provide the single electron device.

Correspondingly, this Example further provides a preparation method for the single hole device.

The preparation method for the single hole device is the same as the step of the preparation method for the single hole device provided by Example 1 except that the solute of the film forming-solution in Step 3 is replaced by the composite material provided in the Example.

### Example 9

This Example provides a composite material, including a hole transport material and a voltage stabilizer, where the hole transport material is TFB, the voltage stabilizer includes AOHBP and 5,5′-methylenebis(2-hydroxy-4-methoxybenzophenone), and a mass ratio of AOHBP, 5,5′-methylenebis(2-hydroxy-4-methoxybenzophenone) and TFB is 0.5:0.5:10.

In this Example, a preparation method for the composite material includes: the voltage stabilizer AOHBP, the voltage stabilizer 5,5′-methylenebis(2-hydroxy-4-methoxybenzophenone) and the hole transport material TFB in a mass ratio of 0.5:0.5:10 were provided, and were uniformly mixed to obtain the composite material.

In addition, this Example further provides a quantum dot light-emitting diode, which is only different from the quantum dot light-emitting diode provided by the Example 1 in that the material in the hole transport layer of the quantum dot light-emitting diode provided in the Example 1 was replaced by the composite material provided in this Example, and the remaining parts are the same as those of the quantum dot light-emitting diode provided by Example 1.

In addition, this Example further provides a preparation method for the quantum dot light-emitting diode, which is only different from Step 3 of the preparation method for the quantum dot light-emitting diode provided by Example 1 in that the solute of the film forming-solution in Step 3 of the preparation method for the quantum dot light-emitting diode provided by Example 1 was replaced with the composite material provided by this Example.

In order to perform testing, this Example further provides a single hole device (HOD) corresponding to the quantum dot light-emitting diode.

The single hole device is the same as the single hole device provided by the Example 1 in that the material in the hole transport layer of the single hole device provided by the Example 1 was replaced with the composite material provided by this Example, and the remaining parts are the same as those of the single hole device provided by Example 1.

Since the single electron device corresponding to the quantum dot light-emitting diode in this Example is the same as the single electron device provided in the Example 1, this Example did not additionally provide the single electron device.

Correspondingly, this Example further provides a preparation method for the single hole device.

The preparation method for the single hole device is the same as the step of the preparation method for the single hole device provided by Example 1 except that the solute of the film forming-solution in Step 3 is replaced by the composite material provided in the Example.

### Example 10

This Example provides a composite material, including a hole transport material and a voltage stabilizer, where the hole transport material is TFB, the voltage stabilizer includes AOHBP and 2-hydroxy-4-(methacryloyloxy)benzophenone, and a mass ratio of AOHBP, 2-hydroxy-4-(methacryloyloxy)benzophenone and TFB is 0.5:0.5:10.

In this Example, a preparation method for the composite material includes: the voltage stabilizer AOHBP, the voltage stabilizer 2-hydroxy-4-(methacryloyloxy)benzophenone and the hole transport material TFB in a mass ratio of 0.5:0.5:10 were provided, and were uniformly mixed to obtain the composite material.

In addition, this Example further provides a quantum dot light-emitting diode, which is only different from the quantum dot light-emitting diode provided by the Example 1 in that the material in the hole transport layer of the quantum dot light-emitting diode provided in the Example 1 was replaced by the composite material provided in this Example, and the remaining parts are the same as those of the quantum dot light-emitting diode provided by Example 1.

In addition, this Example further provides a preparation method for the quantum dot light-emitting diode, which is only different from Step 3 of the preparation method for the quantum dot light-emitting diode provided by Example 1 in that the solute of the film forming-solution in Step 3 of the preparation method for the quantum dot light-emitting diode provided by Example 1 was replaced with the composite material provided by this Example.

In order to perform testing, this Example further provides a single hole device (HOD) corresponding to the quantum dot light-emitting diode.

The single hole device is the same as the single hole device provided by the Example 1 in that the material in the hole transport layer of the single hole device provided by the Example 1 was replaced with the composite material provided by this Example, and the remaining parts are the same as those of the single hole device provided by Example 1.

Since the single electron device corresponding to the quantum dot light-emitting diode in this Example is the same as the single electron device provided in the Example 1, this Example did not additionally provide the single electron device.

Correspondingly, this Example further provides a preparation method for the single hole device.

The preparation method for the single hole device is the same as the step of the preparation method for the single hole device provided by Example 1 except that the solute of the film forming-solution in Step 3 is replaced by the composite material provided in the Example.

### Example 11

This Example provides a composite material including a hole transport material and a voltage stabilizer, where the hole transport material is PVK, the voltage stabilizer is AOHBP, and a mass ratio of AOHBP to PVK is 1:20.

In this Example, a preparation method for the composite material includes: the voltage stabilizer AOHBP and the hole transport material PVK in a mass ratio of 1:20 were provided, and were uniformly mixed to obtain the composite material.

In addition, this Example further provides an organic light-emitting diode including an anode, a hole injection layer, a hole transport layer, an organic light-emitting layer, an electron transport layer and a cathode which are sequentially stacked.

A thickness of the anode is 100 nm, and a material of the anode is FTO; a thickness of the hole injection layer is 25 nm, and a material of the hole injection layer is CuPc; a thickness of the hole transport layer is 25 nm, and a material of the hole transport layer is the composite material provided by this Example; a thickness of the quantum dot light-emitting layer is 25 nm, and a material of the organic light-emitting layer is Alq3; a thickness of the electron transport layer is 30 nm, and a material of the electron transport layer is ZnO; and a thickness of the cathode is 100 nm, and a material of the cathode is Ag.

In addition, this Example further provides a preparation method for the organic light-emitting diode, and the method includes the following steps:
Step 1: a glass substrate provided with an FTO anode was provided;
Step 2: a CuPc solution was inkjet printed on the surface of the FTO anode to obtain a hole injection layer with a thickness of 25 nm;
Step 3: a film-forming solution of the hole transport layer was inkjet printed on the surface of the hole transport layer to obtain a hole transport layer with a thickness of 25 nm, a solvent of the film-forming solution was chlorobenzene, and a solute of the film-forming solution was the composite material provided by this Example;
Step 4: Alq3 was evaporated on the hole transport layer to obtain an organic light-emitting layer with a thickness of 25 nm;
Step 5: a ZnO solution was inkjet printed on the organic light-emitting layer to obtain an electron transport layer with a thickness of 30 nm;
Step 6: the glass substrate with the prepared electron transport layer was placed into a vacuum cavity, silver was evaporated on the electron transport layer to obtain a cathode with a thickness of 100 nm, and an organic light-emitting diode was obtained by packaging.

### Example 12

This Example provides a composite material including a hole transport material and a voltage stabilizer, where the hole transport material is TPD, the voltage stabilizer is AOHBP, and a mass ratio of AOHBP to TPD is 1:2.

In this Example, a preparation method for the composite material includes: the voltage stabilizer AOHBP and the hole transport material TPD in a mass ratio of 1:2 were provided, and were uniformly mixed to obtain the composite material.

In addition, this Example further provides an organic light-emitting diode including an anode, a hole injection layer, a hole transport layer, an organic light-emitting layer, an electron transport layer and a cathode which are sequentially stacked.

A thickness of the anode is 100 nm, and a material of the anode is IZO; a thickness of the hole injection layer is 25 nm, and a material of the hole injection layer is TCNQ; a thickness of the hole transport layer is 25 nm, and a material of the hole transport layer is the composite material provided by this Example; a thickness of the quantum dot light-emitting layer is 25 nm, and a material of the organic light-emitting layer is Alq3; a thickness of the electron transport layer is 30 nm, and a material of the electron transport layer is TiO₂; and a thickness of the cathode is 100 nm, and a material of the cathode is Al.

In addition, this Example further provides a preparation method for the organic light-emitting diode, and the method include the following steps:
Step 1: a glass substrate prepared with an Al cathode was provided;
Step 2: a TiO₂ solution was inkjet printed on the surface of the Al cathode to obtain an electron transport layer with a thickness of 30 nm;
Step 3: Alq3 was evaporated on the surface of the electron transport layer to obtain an organic light-emitting layer with a thickness of 25 nm;
Step 4: a film-forming solution of the hole transport layer was inkjet printed on the surface of the hole transport layer to obtain a hole transport layer with a thickness of 25 nm, a solvent of the film-forming solution was chlorobenzene, and a solute of the film-forming solution was the composite material provided by this Example;
Step 5: a TCNQ solution was inkjet printed on the hole transport layer to obtain a hole injection layer with a thickness of 25 nm;
Step 6: an IZO anode with a thickness of 100 nm was deposited on the hole injection layer, and an organic light-emitting diode was obtained by packaging.

### COMPARATIVE EXAMPLE

The Comparative Example provides a quantum dot light-emitting diode, which is only different from the quantum dot light-emitting diode provided by the Example 1 in that the material in the hole transport layer of the quantum dot light-emitting diode provided by Example 1 was replaced by TFB, and the remaining parts are the same as those of the quantum dot light-emitting diode provided by Example 1.

In order to perform testing, this Example further provides a single hole device (HOD) corresponding to the quantum dot light-emitting diode.

Since the single electron device corresponding to the quantum dot light-emitting diode in this Example is the same as the single electron device provided by Example 1, this Comparative Example did not additionally provide the single electron device.

The single-hole device corresponding to the quantum dot light-emitting diode in this Example only replaces the material in the hole transport layer of the single-hole device provided by Example 1 with TFB, and the remaining parts are the same as those of the single-hole device provided by Example 1.

The quantum dot light-emitting diodes and the single-hole devices provided in Examples 1-12 and the Comparative Example are tested, and the test results are shown in Table 1.

TABLE 1

| | Current density | | External | Life- |
|---|---|---|---|---|
| | of HOD device | | quantum | time |
| | at 8 V (mA · | Hole mobility | efficiency | T95 |
| | cm⁻²) | (×10⁻⁶ cm²V⁻¹s⁻¹) | (%) | (h) |
| Example 1 | 135.89 | 108.65 | 11.41 | 99.63 |
| Example 2 | 256.21 | 174.81 | 16.78 | 165.47 |
| Example 3 | 98.35 | 61.54 | 9.72 | 62.38 |
| Example 4 | 175.29 | 130.46 | 12.67 | 134.59 |
| Example 5 | 183.73 | 139.62 | 13.79 | 142.69 |
| Example 6 | 171.79 | 126.52 | 12.14 | 126.98 |
| Example 7 | 165.07 | 120.55 | 11.59 | 116.22 |
| Example 8 | 161.11 | 115.37 | 11.22 | 110.84 |
| Example 9 | 187.21 | 148.27 | 14.89 | 145.93 |
| Example 10 | 209.93 | 159.68 | 15.28 | 155.62 |
| Example 11 | 185.64 | 126.47 | 13.22 | 136.78 |
| Example 12 | 173.49 | 118.69 | 12.79 | 129.69 |
| Comparative | 57.84 | 52.47 | 8.96 | 48.95 |
| Example 1 | | | | |

The lifetime refers to the time for the brightness of the quantum dot light-emitting diode to decrease to 95% of the maximum brightness thereof under a constant current density (2 mA/cm²).

As can be seen from the data in the table, the external quantum efficiency and the lifetime of the quantum dot light-emitting diode provided by the present disclosure are significantly improved relative to the prior art (the comparative example). Therefore, compared with that prior art, the hole transport layer of the quantum dot light-emitting diode provided by the present disclosure has strong resistance to electron destruction, good device stability, and the carrier transmission of the quantum dot light-emitting diode provided by the present disclosure is more balanced.

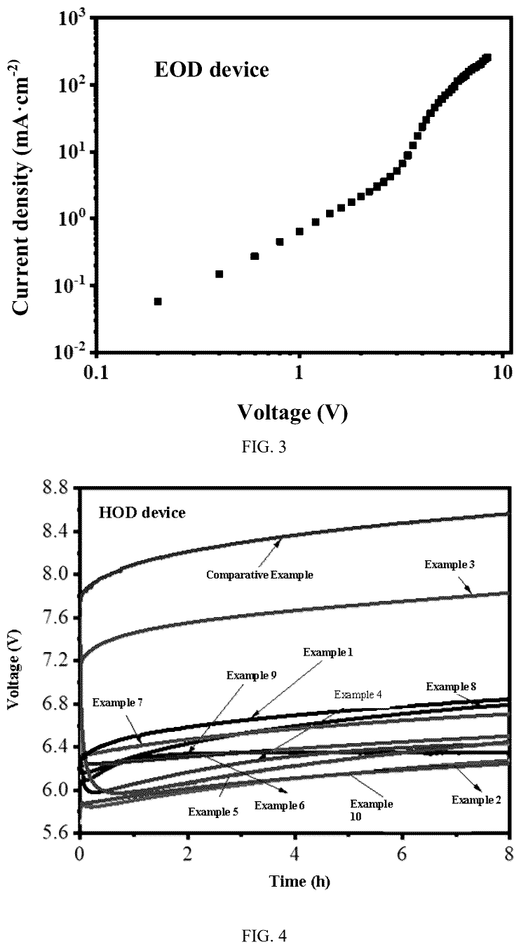

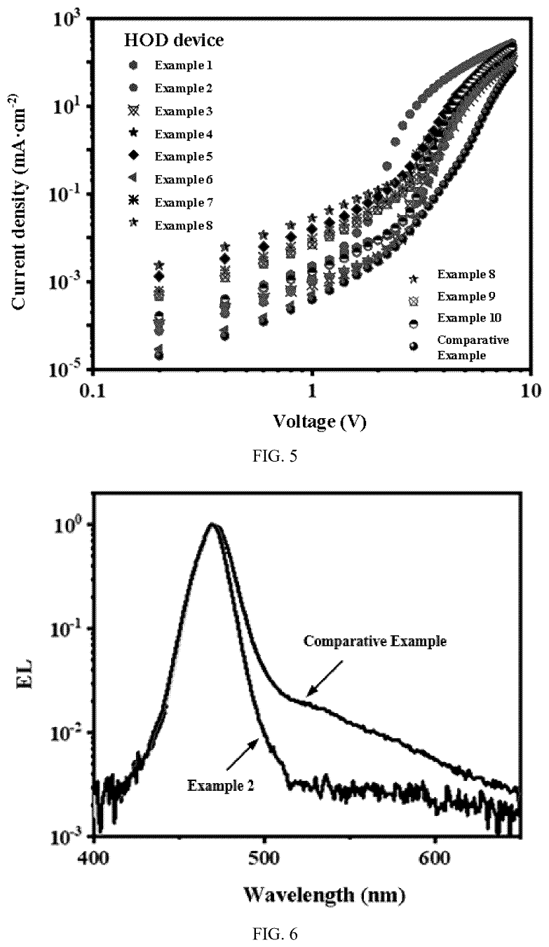

The working voltage of the single electron device provided by Example 1 was tested, and the test result is shown in FIG. 2. The J-V curve of the single electron device was tested, and the test result is shown in FIG. 3. The working voltages of the single hole devices provided by the Examples 1-10 and the Comparative Example were tested, and the test results are shown in FIG. 4. The J-V curves of the single hole devices provided by the Examples 1-10 and the Comparative Example were tested, and the test results are shown in FIG. 5. According to the test results of the working voltages, compared with the Comparative Example, the working voltages of the single hole devices provided by the Examples 1-10 are closer to the working voltage (5.5 V) of the single electron device, and therefore, compared with the prior art, the carrier transmission of the quantum dot light-emitting diode provided by the present disclosure is more balanced. According to the test of the J-V curves, compared with the prior art, in order to achieve the same current density, the quantum dot light-emitting diode provided by the present disclosure requires a smaller voltage, and therefore, the quantum dot light-emitting diode provided by the present disclosure has a higher efficiency.

The EL spectrums of the quantum dot light-emitting diodes provided by Example 2 and Comparative Example are shown in FIG. 6. It can be seen that the quantum dot light-emitting diode provided by the Comparative Example has a small peak at about 530 nm, which is caused by the non-radiative recombination due to the excessive electron injection and the high-energy electron escaping into the hole transport layer. The EL spectrum of the quantum dot light-emitting diode provided by the Example 2 is very symmetrical, which indicates that the hole transport layer of the quantum dot light-emitting diode provided by the present disclosure has a strong ability to resist the electron destruction, may avoid the non-radiative recombination of the device, and therefore, improves the stability and the luminous efficiency of the device.

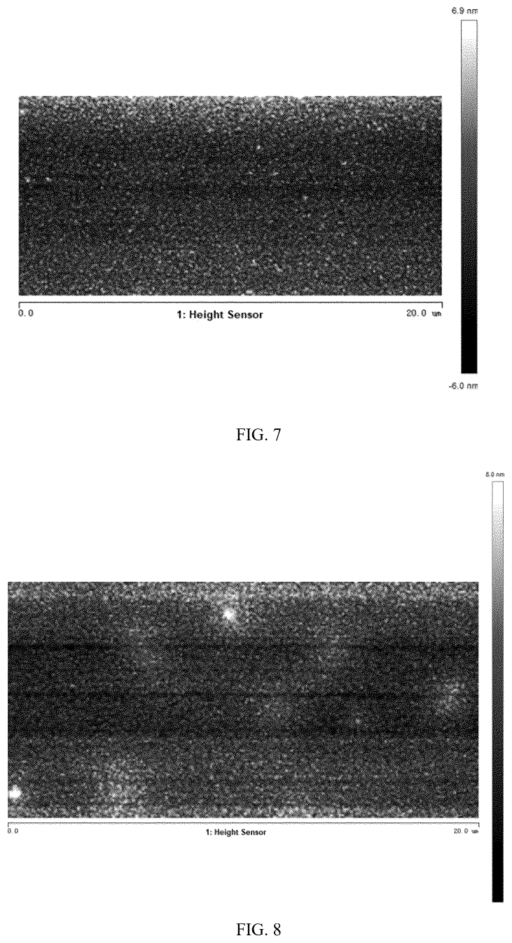

The hole transport layer of the quantum dot light-emitting diode provided by Example 2 and the hole transport layer of the quantum dot light-emitting diode provided by the Comparative Example were tested by AFM, and the test results are shown in FIG. 7 and FIG. 8. The test results show that the surface roughness Rq value of the hole transport layer of the quantum dot light-emitting diode provided by Example 2 is 0.69 nm, and the surface roughness Rq value of the hole transport layer of the quantum dot light-emitting diode provided by the Comparative Example is 1.69 nm. It can be seen that compared with the prior art, the film uniformity of the hole transport layer of the quantum dot light-emitting diode provided by the present disclosure is significantly improved.

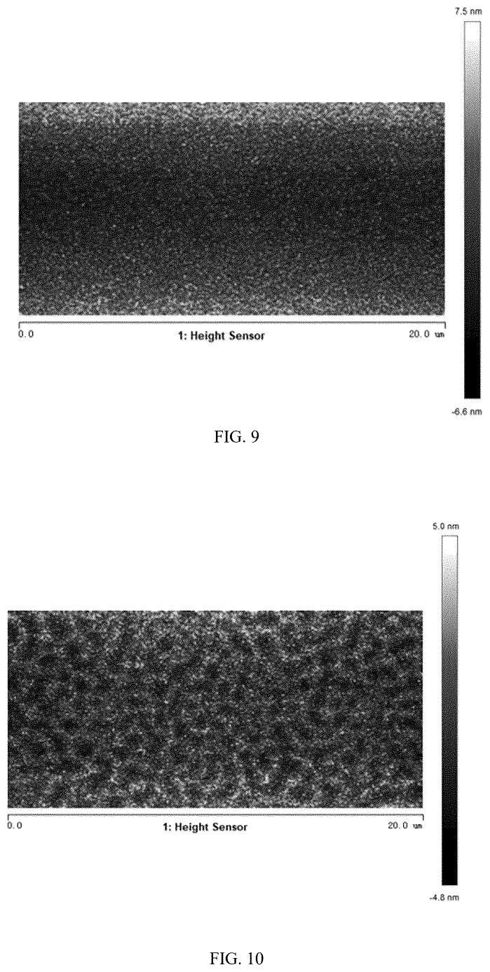

The hole transport layer of the quantum dot light-emitting diode provided by Example 2 and the quantum dot light-emitting layer of the quantum dot light-emitting diode provided by Comparative Example were subjected to AFM testing, and the testing results are shown in FIG. 9 and FIG. 10. The testing results show that the surface roughness Rq value of the quantum dot light-emitting layer of the quantum dot light-emitting diode provided by Example 2 is 0.98 nm, and the surface roughness Rq value of the quantum dot light-emitting layer of the quantum dot light-emitting diode provided by the Comparative Example is 2.14 nm. It can be seen that compared with the prior art, the film uniformity of the quantum dot light-emitting layer of the quantum dot light-emitting diode provided by the present disclosure is also significantly improved. In addition, the thickness of the quantum dot light-emitting layer of the quantum dot light-emitting diode provided by Example 2 is 23.56 nm, and the thickness of the quantum dot light-emitting layer of the quantum dot light-emitting diode provided by the Comparative Example is 30.45 nm. It can be seen that under the same process conditions, compared with the quantum dot light-emitting diode in the Comparative Example, the film thickness of the quantum dot light-emitting layer of the quantum dot light-emitting diode provided by Example 2 is thinner (a thinner film thickness of the quantum dot light-emitting layer is conducive to improving the device lifetime), that is, the improvement of the film uniformity of the hole transport layer is conducive to the improvement of the film uniformity of the quantum dot light-emitting layer, and then the thickness of the quantum dot light-emitting layer is reduced under the same process conditions.

The hole transport layer of the light-emitting device includes the composite material described above, the voltage stabilizer in the composite material is a substituted aromatic ketone, the substituted aromatic ketone has good conjugation characteristics and electron delocalization, therefore, the composite material has good electron affinity, and the composite material has good π-π stacking effect between molecules, therefore, the composite material has good charge transport performance. Thus, based on the strong conjugation effect and electron delocalization of the voltage stabilizer molecules in the composite material, the voltage stabilizer may absorb the energy of the electrons by excitation or ionization, and may especially absorb the energy of high-energy electrons induced by electrons aggregation, and greatly weaken the kinetic energy of the high-energy electrons and reduce the number of the high-energy electrons, thereby reducing the damage of the electrons to the material of the hole transport layer, improving the ability of the material of the hole transport layer to resist the damage of the electrons, and further improving the current density, hole mobility, external quantum efficiency and lifetime of the light-emitting device.

The technical solutions provided by the embodiments of the present disclosure are described in detail above. The principles and embodiments of the present disclosure have been described with reference to specific embodiments, and the description of the above embodiments is merely intended to aid in the understanding of the method of the present disclosure and its core idea. Meanwhile, for those skilled in the art, the specific implementation manners and application ranges may be changed according to the idea of the present disclosure. In conclusion, the content of the specification should not be understood as a limitation on the present disclosure.

1. A composite material, comprising:
a hole transport material and a voltage stabilizer;
wherein the voltage stabilizer comprises a substituted aromatic ketone, and at least one substituent of the aromatic ketone is an electron-donating group.

2. The composite material of claim 1, wherein the electron-donating group comprises one or more of a hydroxyl, an alkoxy, a phenoxy, a benzyloxy, and an acyloxy.

3. The composite material of claim 1, wherein the voltage stabilizer comprises a substituted aromatic ketone having 2 to 5 benzene ring structures.

4. The composite material of claim 3, wherein the aromatic ketone having 2 to 5 benzene ring structures comprises one or more of 4-allyloxy-2-hydroxybenzophenone, 2-hydroxy-4-(methacryloyloxy)benzophenone, 4′-phenoxyacetophenone, 4′-benzyloxy-2′-hydroxyacetophenone, 5,5′-methylenebis(2-hydroxy-4-methoxybenzophenone), 2-hydroxy-4-methoxybenzophenone, and 4-hydroxy-4′-phenoxybenzophenone.

5. The composite material of claim 1, wherein a mass ratio of the voltage stabilizer to the hole transport material is 1: (2-20).

6. The composite material of claim 1, wherein the hole transport material comprises at least one of TFB, CuPc, PVK, Poly-TPD, DNTPD, TCATA, TCCA, CBP, TPD, NPB, NPD, PEDOT:PSS, TAPC, MCC, F4-TCNQ, HATCN, 4,4′,4′-tris(N-3-methylphenyl-N-phenylamino) triphenylamine, polyaniline, a transition metal oxide, a transition metal sulfide, a transition metal stannide, doped graphene, undoped graphene, and C60.

7. A light-emitting device, comprising:
a cathode;
an anode;
a light-emitting layer; and
a hole transport layer;
wherein a material of the hole transport layer comprises a composite material comprising a hole transport material and a voltage stabilizer: the voltage stabilizer comprises a substituted aromatic ketone, and at least one substituent of the aromatic ketone is an electron-donating group.

8. The light-emitting device of claim 7, wherein a material of the anode and a material of the cathode respectively independently comprise one or more of a metal, a carbon material, and a metal oxide; the metal comprises one or more of Al, Ag, Cu, Mo, Au, Ba, Ca, Yb, and Mg; the carbon material comprises one or more of graphite, carbon nanotube, graphene, and carbon fiber; the metal oxide comprises a doped or undoped metal oxide, which comprises one or more of ITO, FTO, ATO, AZO, GZO, IZO, MZO, and AMO; the anode and the cathode may further comprise a composite electrode with metal sandwiched between doped or undoped transparent metal oxides; the composite electrode comprises one or more of AZO/Ag/AZO, AZO/Al/AZO, ITO/Ag/ITO, ITO/Al/ITO, ZnO/Ag/ZnO, ZnO/Al/ZnO, ZnS/Ag/ZnS, ZnS/Al/ZnS, TiO₂/Ag/TiO₂, and TiO₂/Al/TiO₂; and
a material of the light-emitting layer comprises one or more of an organic light-emitting material and a quantum dot light-emitting material; the organic light-emitting material comprises at least one of 4,4′-bis(N-carbazole)-1,1′-biphenyl:tris[2-(p-tolyl)pyridine-C2,N) iridium(III), 4,4′,4″-tris(carbazole-9-yl)triphenylamine:tris[2-(p-tolyl)pyridine-C2,N) iridium, a diaromatic anthracene derivative, a stilbene aromatic derivative, a pyrene derivative, a fluorene derivative, TBPe fluorescent material, TTPX fluorescent material, TBRb fluorescent material, and DBP fluorescent material; the quantum dot light-emitting material comprises at least one of a single-structure quantum dot, a core-shell structure quantum dot, and a perovskite semiconductor material; a material of the single-structure quantum dot, a core material of the core-shell structure quantum dot and a shell material of the core-shell structure quantum dot respectively comprise at least one of an II-VI compound, an IV-VI compound, an III-V compound, and an I-III-VI compound; the II-VI compound comprises at least one of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the IV-VI compound comprises at least one of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the III-V compound comprises at least one of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; the I-III-VI compound comprises at least one of CuInS₂, CuInSe₂, and AgInS₂; the perovskite semiconductor material comprises a doped or non-doped inorganic perovskite semiconductor, or an organic-inorganic hybrid perovskite semiconductor; the inorganic perovskite semiconductor has a general structure of AMX₃, where, A is a Cs⁺ ion, M is a divalent metal cation, and X is a halide anion; the organic-inorganic hybrid perovskite semiconductor has a general structure of BMX₃, where B is an organic amine cation, M is a divalent metal cation, and X is a halide anion; the divalent metal cation comprises at least one of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺; the halide anion comprises at least one of Cl⁻, Br⁻, and I⁻; the organic amine cation comprises CH₃(CH₂)ₙ₋₂NH³⁺ or [NH₃(CH₂)ₙNH₃]²⁺, where n≥2.

9. The light-emitting device according to claim 7, wherein the light-emitting device further comprises a hole injection layer disposed between the anode and the hole transport layer, a material of the hole injection layer comprises poly(3,4-ethylenedioxythiophene)-polystyrenesulfonate, 2,3,5,6-tetrafluoro-7,7′,8,8′-tetracyanoquinodimethane, copper phthalocyanine, 1,4,5,8,9,11-hexaazatriphenylenehexacarbonitrile (HATCN), NiOₓ, MoOₓ, WOₓ, CrOₓ, CuO, MoSₓ, MoSeₓ, WSₓ, WSeₓ, and CuS, where x is in a range from 1 to 3; and
the light-emitting device further comprises one or both of an electron transport layer and an electron injection layer disposed between the cathode and the light-emitting layer, a material of the electron transport layer and a material of the electron injection layer comprises one or both of an inorganic material and an organic material; the inorganic material comprises one or more of a doped or undoped zinc oxide, barium oxide, aluminum oxide, nickel oxide, titanium oxide, tin oxide, tantalum oxide, zirconium oxide, lithium titanium oxide, zinc aluminum oxide, zinc manganese oxide, zinc tin oxide, zinc lithium oxide, indium tin oxide, cadmium sulfide, zinc sulfide, molybdenum sulfide, tungsten sulfide, copper sulfide, zinc stannate, indium phosphide, gallium phosphide, copper indium sulfide, copper gallium sulfide, and barium titanate; a doping element of the doped or undoped zinc oxide comprises one or more of aluminum, magnesium, lithium, manganese, yttrium, lanthanum, copper, nickel, zirconium, cerium, and gadolinium; the organic material comprises one or more of a quinoxaline compound, an imidazole compound, a triazine compound, a fluorene-containing compound, and a hydroxyquinoline compound.

10. A method for preparing a light-emitting device, comprising:
providing a light-emitting device preform and a composite material, the composite material comprises a hole transport material and a voltage stabilizer, the voltage stabilizer comprises a substituted aromatic ketone, and at least one substituent of the aromatic ketone is an electron-donating group; and
depositing the composite material on the light-emitting device preform to form a hole transport layer.

11. The preparation method according to claim 10, wherein the electron-donating group comprises one or more of a hydroxyl, an alkoxy, a phenoxy, benzyloxy, and an acyloxy.

12. The preparation method according to claim 10, wherein the voltage stabilizer comprises a substituted aromatic ketone having 2 to 5 benzene ring structures.

13. The preparation method according to claim 12, wherein the aromatic ketone having 2 to 5 benzene ring structures comprises one or more of 4-allyloxy-2-hydroxybenzophenone, 2-hydroxy-4-(methacryloyloxy)benzophenone, 4′-phenoxyacetophenone, 4′-benzyloxy-2′-hydroxyacetophenone, 5,5′-methylenebis(2-hydroxy-4-methoxybenzophenone), 2-hydroxy-4-methoxybenzophenone, and 4-hydroxy-4′-phenoxybenzophenone.

14. The preparation method according to claim 10, wherein a mass ratio of the voltage stabilizer to the hole transport material is 1: (2-20).

15. The preparation method according to claim 10, after depositing the composite material on the light-emitting device preform and before the hole transport layer is formed, the method further comprises: ultraviolet light irradiating for 2 to 10 minutes.

16. The preparation method according to claim 10, wherein depositing the composite material on the light-emitting device preform comprises:
providing a solvent and the composite material, and mixing the solvent and the composite material to obtain a film-forming solution; and
depositing the film-forming solution on the light-emitting device preform to form the hole transport layer.

17. The preparation method according to claim 16, wherein mixing the solvent and the composite material is performed by stirring at 40-60 °C for 2-4 hours.

18. The preparation method according to claim 16, wherein the concentration of the composite material in the film-forming solution ranges from 4 mg/mL to 10 mg/mL.

19. The preparation method according to claim 16, wherein the solvent comprises a non-polar organic solvent, and the non-polar organic solvent comprises one or more of an alkane solvent, an alkene solvent, and an aromatic hydrocarbon solvent.

20. The preparation method according to claim 19, wherein the alkane solvent comprises one or more of n-hexane, n-heptane, n-octane, cyclohexane, cycloheptane, chloroform, tetradecane, and cyclooctane; the alkene solvent comprises one or more of 1-decene, 1-dodecene, 1-tetradecene, and 1-hexadecene; and the aromatic hydrocarbon solvent comprises one or more of benzene, toluene, chlorobenzene, and xylene.
